(19) United States
(12) Patent Application Publication
(10) Pub. No.: US 2025/0348726 A1
(43) Pub. Date: Nov. 13, 2025

(54) ANALOG COMPUTING METHOD AND APPARATUS FOR PERFORMING DEEP NEURAL NETWORK MODELS WITH HIGH ACCURACY

(71) Applicant: Intelligent HW, Inc., Lewes, DE (US)

(72) Inventors: Seok Man HONG, Seoul (KR); Hwan Jun ZANG, Seongnam-si (KR)

(21) Appl. No.: 19/203,813

(22) Filed: May 9, 2025

(30) Foreign Application Priority Data
May 10, 2024 (KR) 10-2024-0062151

(51) Int. Cl. G06N 3/065; G06F 7/544

(52) U.S. Cl. CPC G06N 3/065; G06F 7/5443

(57) ABSTRACT

An analog computing apparatus for performing a multiply-accumulate (MAC) operation includes a memory array including a non-volatile memory cell in which a weight is stored, an input unit including a digital-analog converter (DAC), an output unit including a multiplexer and an analog-to-digital converter (ADC), and a control unit for controlling the memory array, the input unit, and the output unit, wherein the control unit may apply the input signal to the memory array such that the MAC operation is performed through the weight, select a current signal output from each of a plurality of output lines of the memory array, which are the results of the MAC operation, one by one through the multiplexer, classify the grade of the selected current signal according to a current size, control the current signal according to the classified grade, and convert the current signal into a digital signal through the analog-digital converter.

### CROSS REFERENCE TO RELATED APPLICATION

The present application claims priority to Korean Patent Application No. 10-2024-0062151, filed on May 10, 2024, the entire contents of which are incorporated herein by reference for all purposes.

### BACKGROUND OF THE INVENTION

### 1. Field of the Invention

In analog computing for performing a deep neural network model, the present invention relates to an analog computing method and an analog computing apparatus which are characterized by controlling and performing conversion of an analog output signal into a digital signal for each output line.

### 2. Description of the Related Art

A human brain consists of numerous nerve cells called neurons. Each neuron is connected to hundreds to thousands of other neurons through a connection site called a synapse. In order to imitate human intelligence, an operating principle of a biological neuron and a connection relationship between neurons are modeled as an artificial neural network (ANN) model.

A deep neural network (DNN) is one type of an artificial neural network, and shows excellent performance in various fields such as image recognition, voice recognition, natural language processing, and recommendation systems. Particularly, based on a large amount of data and high computing power, the performance of a deep neural network is continuously improving, and has become a key technology in the field of artificial intelligence.

Such a deep neural network is a neural network having several hidden layers between an input layer and an output layer. A deep neural network consists of an input layer, several hidden layers, and an output layer. Each layer consists of a number of neurons (nodes), and neurons of adjacent layers are connected to each other. In the above-described deep neural network, input data propagates sequentially from the input layer to the output layer. Each neuron receives an input from neurons of a previous layer, calculates a weighted sum, and delivers an output value to the next layer through an activation function.

In order to implement the above-described deep neural network, a digital operator using digital computing was developed in the past. However, although a digital operator boasts high accuracy, the digital operator inevitably consumes a large amount of energy due to problems such as limitations in parallel processing and memory barriers, and is problematic for application in various fields due to a high price as a result of its large size, and the like.

In order to overcome the above-described problems, analog in-memory computing, which is a method for storing a weight in a non-volatile memory and using the weight to perform a MAC operation, has recently been researched and developed substantially since the method is capable of performing large-scale parallel processing, significantly reducing energy usage as there is no memory barrier, and being manufactured at a low cost.

Meanwhile, a matrix operation result obtained through the performance of a deep neural network is output as an analog current signal. Therefore, a step of digitizing the analog current signal is required, and it is necessary to maintain high accuracy in the digitalization of the signal.

### SUMMARY OF THE INVENTION

An object of the invention is to provide an apparatus and a method for increasing the accuracy in a MAC operation through analog computing.

In order to achieve the above-described object, the invention provides an analog computing apparatus, which is an analog computing apparatus for performing a multiply-accumulate (MAC) operation, the apparatus including a memory array including a non-volatile memory cell in which a weight is stored, an input unit including a digital-analog converter (DAC), thereby inputting an input signal to the memory array, an output unit including a multiplexer and an analog-to-digital converter (ADC), and a control unit for controlling the memory array, the input unit, and the output unit, wherein the control unit may apply the input signal to the memory array such that the MAC operation is performed through the weight, select a current signal output from each of a plurality of output lines of the memory array, which are the results of the MAC operation, one by one through the multiplexer, classify the grade of the selected current signal according to a current size, control the current signal according to the classified grade, and convert the current signal into a digital signal through the analog-digital converter.

In addition, the analog computing apparatus according to an embodiment of the invention has the output unit including a plurality of I-V converters, wherein the multiplexer may be disposed between the output line of the memory array and the plurality of I-V converters, and the plurality of I-V converters may be connected in parallel to each other and have different resistances or different capacitances, and the control performed by the control unit according to the classified grade may be to convert the selected current signal into a voltage signal through any one of the plurality of I-V converters according to the classified grade and transmit the voltage signal to the analog-digital converter.

In addition, the analog computing apparatus according to an embodiment of the invention further includes a demultiplexer disposed between the multiplexer and the plurality of I-V converters, wherein the control performed by the control unit according to the classified grade may be to send the selected current signal to any one of the plurality of I-V converters through the demultiplexer according to the classified grade, thereby converting the selected current signal into a voltage signal, and transmit the voltage signal to the analog-digital converter.

In addition, the analog computing apparatus according to an embodiment of the invention further includes an additional multiplexer disposed between the plurality of I-V converters and the analog-digital converter, wherein the control performed by the control unit according to the classified grade may be to transmit the selected current signal to all of the plurality of I-V converters, select one of the plurality of voltage signals converted from the plurality of I-V converters through the additional multiplexer according to the classified grade, and transmit the selected voltage signal to the analog-digital converter.

In addition, the analog computing apparatus according to an embodiment of the invention has the output unit including an I-V converter disposed between the multiplexer and the analog-digital converter, wherein the analog-digital converter is a voltage-mode ADC, and the control performed by the control unit according to the classified grade may be to change a reference voltage of the voltage-mode ADC according to the classified grade of the selected current signal.

In addition, the analog computing apparatus according to an embodiment of the invention has the output unit in which the analog-digital converter is a current-mode ADC, and the control performed by the control unit according to the classified grade may be to change a reference current of the current-mode ADC according to the classified grade of the selected current signal.

In addition, the analog computing apparatus according to an embodiment of the invention has the output unit in which the analog-digital converter is an oscillator-based ADC and has a plurality of capacitors having different capacitances thereinside, and the control performed by the control unit according to the classified grade may be to allow the selected current signal to use any one of the plurality of different capacitors in the oscillator-based ADC according to the classified grade.

Meanwhile, the invention may provide an analog computing method, which is an analog computing method for storing a weight in a non-volatile memory device disposed in a memory array and performing a multiply-accumulate (MAC) operation by using the weight, the method including (a) a weight storage step of storing the weight, which is included in each layer in a model of a neural network including a plurality of layers, in the non-volatile memory device disposed in the memory array, (b) a MAC operation step of applying an input signal to the memory array, thereby performing the MAC operation, and outputs the MAC operation result as a current signal, (c) a step of determining a grade of the current signal output for each output line of the memory array according to a current size, and (d) a step of controlling the current signal according to the determined grade, thereby converting the current signal into a digital signal.

In addition, in an embodiment of the analog computing method according to the invention, the determination of the grade in the step (c) may be a result predicted according to the neural network model.

In addition, in an embodiment of the analog computing method according to the invention, the determination of the grade in the step (c) may be a result obtained through sensing the current signal for each output line.

### Advantageous Effects

An analog computing apparatus according to the invention may effectively increase the accuracy of an analog MAC operation result, thereby broadening the field of application of the analog computing apparatus.

### BRIEF DESCRIPTION OF THE DRAWINGS

FIG. 1 is a schematic diagram illustrating a process in which a MAC operation is performed through analog computing;

FIG. 2 is a schematic diagram illustrating the entire analog MAC operation process;

FIG. 3 is a schematic diagram illustrating an analog computing apparatus and an operation of the apparatus according to an embodiment of the invention;

FIG. 4 is a schematic diagram illustrating an analog computing apparatus and an operation of the apparatus according to an embodiment of the invention;

FIG. 5 is a schematic diagram illustrating an apparatus for digitizing a signal and an operation of the apparatus in an analog computing apparatus according to an embodiment of the invention;

FIG. 6 is a schematic diagram illustrating an apparatus for digitizing a signal and an operation of the apparatus in an analog computing apparatus according to an embodiment of the invention;

FIG. 7 is a schematic diagram illustrating an apparatus for digitizing a signal and an operation of the apparatus in an analog computing apparatus according to an embodiment of the invention;

FIG. 8 is a schematic diagram illustrating an apparatus for digitizing a signal and an operation of the apparatus in an analog computing apparatus according to an embodiment of the invention;

FIG. 9 is a schematic diagram illustrating an apparatus for digitizing a signal and an operation of the apparatus in an analog computing apparatus according to an embodiment of the invention;

FIG. 10 is a schematic diagram illustrating an apparatus for digitizing a signal and an operation of the apparatus in an analog computing apparatus according to an embodiment of the invention; and

FIG. 11 is a schematic diagram illustrating the difference in results according to digitization of a signal in an analog computing apparatus according to an embodiment of the invention and in a typical analog computing apparatus.

### DETAILED DESCRIPTION OF THE EXEMPLARY EMBODIMENTS

Hereinafter, embodiments of the present application will be described in detail with reference to the accompanying drawings so that those skilled in the art to which the present application pertains may easily practice the embodiments. The present application may, however, be embodied in many different forms and should not be construed as limited to the embodiments set forth herein.

Throughout the present specification, when a part is referred to as “including” another component, it means the part may further include other components, rather than excluding other components, unless specifically stated otherwise.

The terms “about,” “substantially,” and the like used herein are used in a sense that is close to a numerical value presented with a manufacturing and material tolerance specific to a stated meaning, and is used to prevent an unscrupulous person from abusing a disclosure in which an exact or absolute value is stated in order to facilitate the understanding of the present application. In addition, the term “a step˜ing,” or “a step of ˜,” as used throughout the present specification, does not mean “a step for ˜.”

Throughout the present specification, the term “a combination thereof” included in an expression of the Markush form means one or more mixtures or combinations selected from the group consisting of components described in the expression of the Markush form, and means to include one or more selected from the group consisting of the components.

Throughout the present specification, the description of “A and/or B” means “A or B, or A and B.”

The invention relates to an apparatus and a method for digitizing MAC operation results with high accuracy in analog in-memory computing.

An analog in-memory computing method is a method for storing a weight in a non-volatile memory and using the weight to perform a MAC operation. The above-described analog in-memory computing has been researched and developed substantially since the method is capable of performing large-scale parallel processing, significantly reducing energy usage by solving a memory barrier problem as there is no external memory, and being manufactured at a low cost. Meanwhile, analog computing herein refers to analog in-memory computing.

As described above, an analog MAC operation stores weight information in a non-volatile memory of a memory array and inputs an input signal thereto, thereby performing the MAC operation at once and outputting a MAC operation result.

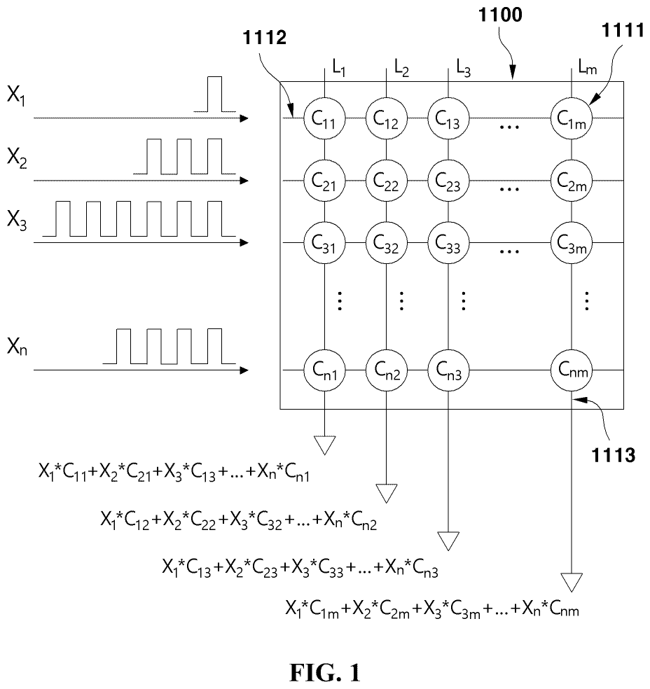

FIG. 1 illustrates the above-described analog MAC operation method. Input signals X₁, X₂, X₃, . . . , and Xₙ are input from an input unit along an input line 1112 of a memory array 1100. Here, the input signal may be expressed by the number of pulses having the same height and width, and various input signals may be expressed not only by the number of pulses, but also by the difference in the widths of pulses or difference in the heights of pulses. Meanwhile, a memory cell 1111 disposed in the memory array 1100 stores a weight through a change in resistance. Therefore, as the input signal is applied to the memory cell in which the weight is stored through several stages of resistance, a current signal is output, which eventually becomes a MAC operation result.

To describe more specifically, when the input signals X₁, X₂, X₃, . . . , and Xₙ are applied to memory cells C₁₁, C₂₁, C₃₁, . . . , and Cₙ₁, each input signal passes through an individual memory cell and is output as an output signal X₁*C₁₁+X₂*C₂₁+X₃*C₁₃+ . . . +Xₙ*Cₙ₁ in the form of a current or a voltage through an output line L₁, and output signals are output in the same manner from the rest of output lines L₂, L₃, . . . , and Lₘ. As a result, input signals simultaneously input pass through the memory cell in which the weight is stored, thereby allowing the analog MAC operation to be performed at once, which enables fast operation with low energy consumption. The MAC operation result output as described above is an analog signal expressed as a current, which is subjected to digitization of a signal an analog-digital converter (ADC).

The non-volatile memory constituting the memory array may be a flash memory. Particularly, among flash memories, an NOR flash memory may exhibit a fast read speed, and thus, is suitable for an inference-type artificial intelligence accelerator.

The above-described flash memory may not only be a single level cell (SLC) which stores 1 bit of information, but also a multi level cell (MLC), a triple level cell (TLC), a quadruple level cell (QLC) or the like which stores 2 or more bits of information, and may be a memory cell which stores 5 or more bits of information. By storing more information in more cells, the size of the memory array may be reduced.

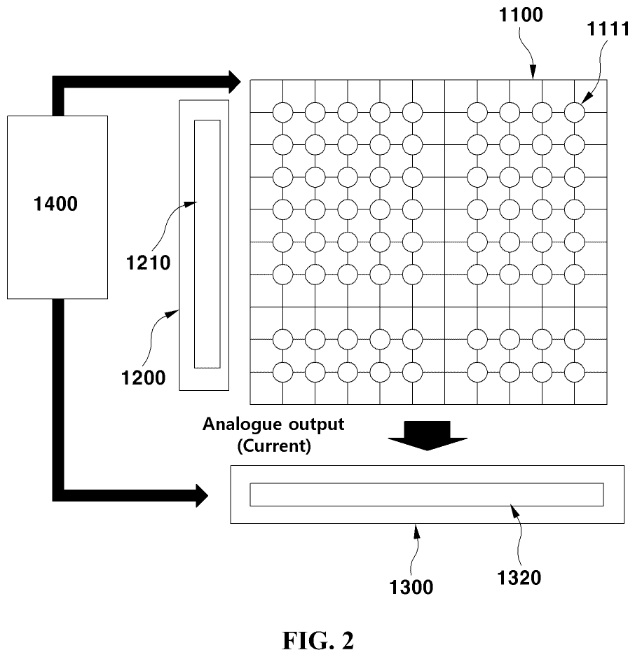

FIG. 2 is a conceptual diagram illustrating the entire analog MAC operation process. When an input signal in an analog form enters the memory array 1100 through a digital-analog converter (DAC) 1210 of an input unit 1200, an analog signal expressed as an electric current is generated due to the resistance of the memory cell 1111 of the memory array 1100 and an analog-digital converter 1320 converts the analog signal into a digital signal. The entire process is controlled through a control unit 1400.

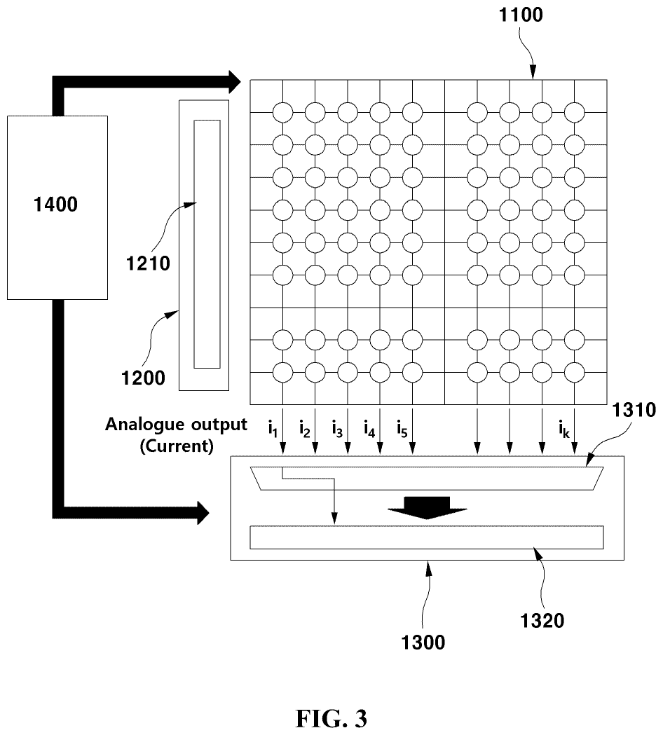

FIG. 3 illustrates an embodiment of an analog computing apparatus according to the invention. By the input signal, the MAC operation result in the memory array 1100 is output as a current signal i₁, i₂, i₃, . . . , and iₖ for each output line. The control unit selects the output current signals one by one for each output line through a multiplexer 1310, classifies the grade according to the size of a current of the selected current signal, controls the current signal according to the classified grade, and converts the current signal into a digital signal through the analog-digital converter 1320. Here, the control according to the grade may be variously performed according to the type of an analog-digital converter.

An analog-digital converter is a device which converts an analog signal into a digital signal, and may be various devices such as a voltage-mode ADC which converts a current signal into a voltage and then comparing the converted voltage with a reference voltage to perform digitization of a signal, a current-mode ADC which compares a current signal itself with a reference current to perform digitization of a signal, and an oscillator-based ADC which converts a current signal into a frequency and counts the value thereof to perform digitization. Meanwhile, if an analog-digital converter is a voltage-mode ADC, a current signal first needs to be converted into a voltage signal, which requires an I-V converter. The I-V converter may be disposed separately from or inside the analog-digital converter, and depending on the method of converting a current into a voltage, the I-V converter may be a simple resistance converter, a transimpedance amplifier, a charge-integrating I-V converter, and the like, and converts a current into a voltage through resistance or into a voltage through capacitance.

As described above, in order to convert a current signal into a digital signal, one or more conversion steps are performed in an analog-digital converter, and each step of conversion uses a reference voltage or reference current resistance of the analog-digital converter, or a resistance or capacitance of the I-V converter. Therefore, according to the size of a current signal, it is necessary to use a reference voltage or reference current of an analog-to-digital converter of appropriate size, a resistance or capacitance of an I-V converter, and the like.

However, in the analog computing apparatus for the analog MAC operation as in the invention, a current signal output from the memory array has a wide range. Therefore, a single unified analog-digital converter or a method of using the same alone may increase an error when performing digitization. That is, an analog-digital converter optimized according to the size of a current signal or a method using the same is required. Therefore, the analog computing apparatus according to the invention classifies the grade according to the size of a current signal for each output line of a memory array, controls the current signal accordingly, and converts the current signal into a digital signal, which may reduce an error.

In the analog computing apparatus according to an embodiment of the invention, an output unit includes an I-V converter together with an analog-digital converter that is a voltage-mode ADC, and a plurality of the I-V converters are connected in parallel to each other, and may have different resistances or capacitances thereinside. Accordingly, the control performed by the control unit may be to send a current signal to any one of the plurality of I-V converters according to the classifies grade, thereby converting the current signal into a voltage signal, and transmit the voltage signal to the analog-digital converter. As described above, since the I-V converter suitable for the size of a current signal converts the current signal into a voltage signal, the possibility of an error may be reduced.

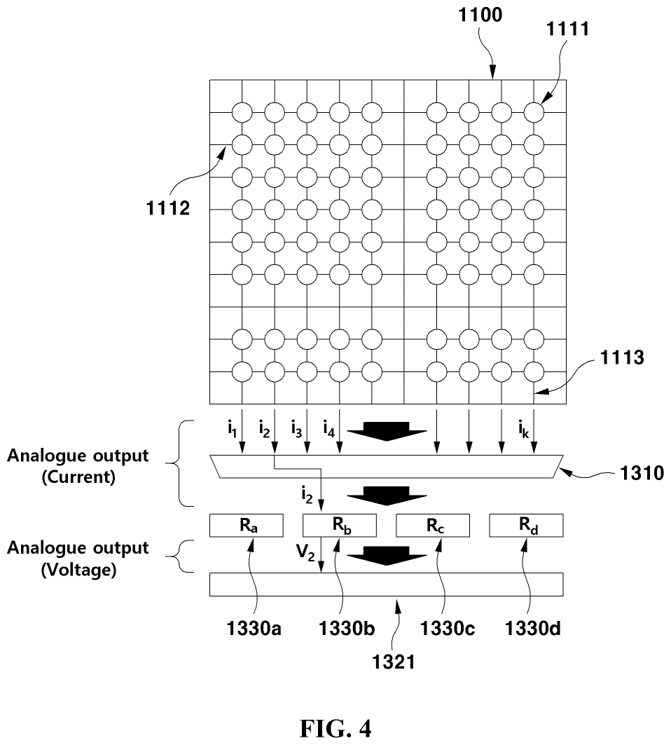

FIG. 4 illustrates an analog computing apparatus according to an embodiment of the invention. First, an analog MAC operation is performed in a memory array 1100 by an input signal applied from an input unit, and as a result, a current signal i₁, i₂, i₃, . . . , and iₖ is output for each output line 1113. The current signal output at this time shows a large difference in the size of a current for each output line 1113 due to the characteristics of a MAC operation.

One of the output current signals is selected through a multiplexer 1310, and according to the size of a current, a selected current signal i₂ is converted into a voltage signal through one I-V converter 1330b of a plurality of I-V converters. The plurality of I-V converters 1330a, 1330b, 1330c, and 1330d have different resistances or capacitances Rₐ, R_{b}, R_{c}, and R_{d}, so that the suitable I-V converter 1330b is selected according to the size of the selected current signal i₂. After the conversion into a voltage signal V₂ through the I-V converter selected as described above, the final digital conversion is performed through a voltage-mode ADC 1321.

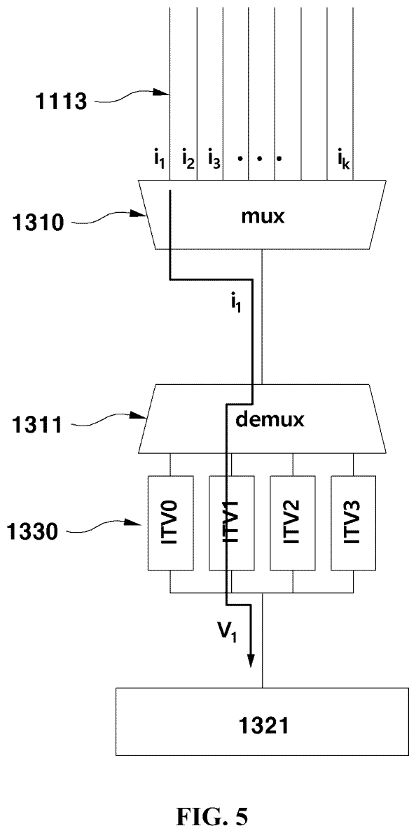

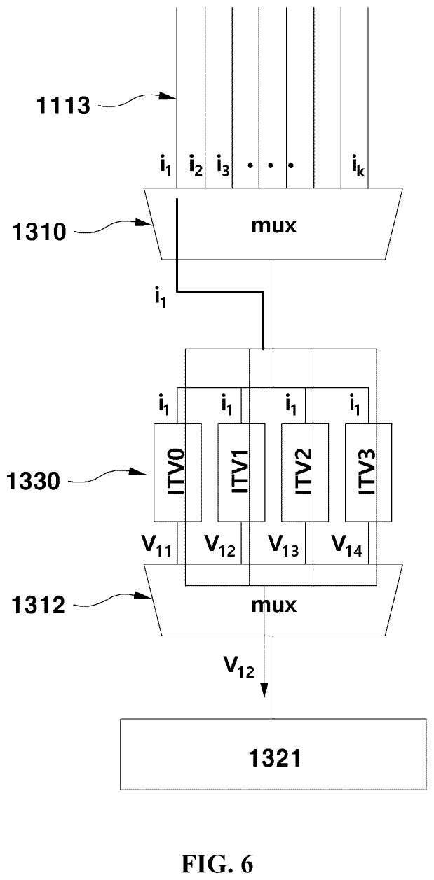

FIGS. 5 and 6 illustrate a possible circuit configuration before a current signal passing through a multiplexer is transmitted to a voltage-mode ADC via a plurality of I-V converters in an embodiment of the invention. FIG. 5 shows that when a current signal passing through a multiplexer 1310 passes through a demultiplexer 1311 again, the current signal may be transmitted to one I-V converter of a plurality of I-V converters 1330, which is selected according to a current range. Here, the I-V converters may be transimpedance amplifiers (TIA) and may have internal resistances different from each other. Through the multiplexer 1310, any one current signal i₁ is selected among current signals i₁, i₂, i₃, . . . , and iₖ from a plurality of output lines 1113 of a memory array, and the selected current signal is transmitted again to one ITV1 of a plurality of TIAs through the demultiplexer 1311 to be finally converted into a voltage signal V₁. The voltage signal converted as described above is converted into a digital signal through a voltage-mode ADC 1321.

Meanwhile, FIG. 6 illustrates a case in which the current signal i₁ selected through the multiplexer 1310 is simultaneously transmitted to the plurality of I-V converters 1330, and any one voltage signal V₁₂ thereof is selected and output through a second multiplexer 1312. The voltage signal V₁₂ output as described above is transmitted to the voltage-mode ADC 1321.

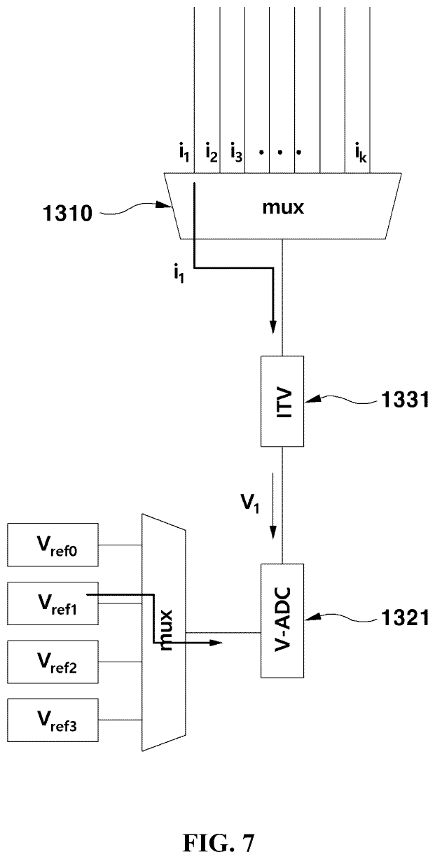

FIG. 7 illustrates an analog computing apparatus according to an embodiment of the invention. An analog-digital converter is a voltage-mode ADC, and is capable of changing a reference voltage according to the size of a current signal output from a memory array. One current signal i₁ of output current signals is selected through a multiplexer 1310, sent to one TIA 1331, converted into a voltage signal V₁, and then converted into a digital signal through a voltage-mode ADC 1321. At this time, in the voltage-mode ADC 1321, one reference voltage V_{ref1} of reference voltages V_{ref0}, V_{ref1}, V_{ref2}, and V_{ref3} is selected according to the size of the selected current signal i₁ or the size of the converted voltage signal V₁, and is used as a reference voltage for the digital signal.

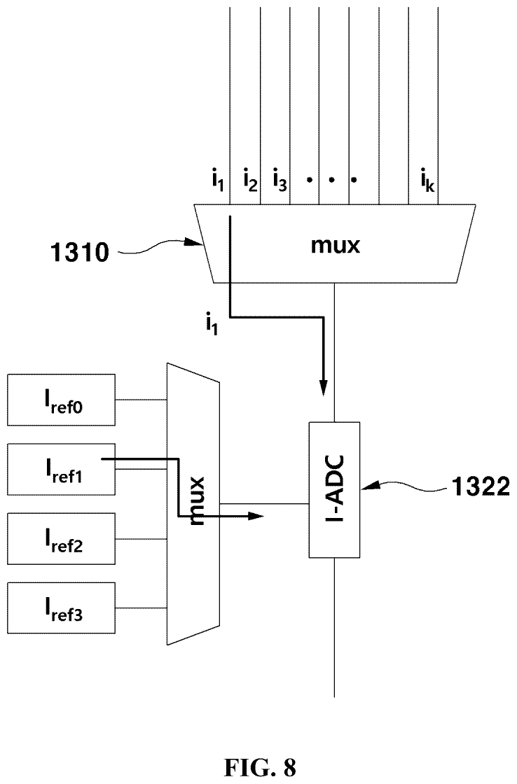

FIG. 8 illustrates an example in which an analog-digital converter, which is a current-mode ADC, changes a reference current according to the size of an output current signal in an analog computing apparatus according to an embodiment of the invention. One current signal i₁ of output current signals is selected through a multiplexer 1310 and converted into a digital signal through a current-mode ADC 1322. At this time, the current mode ADC 1322 selects one reference current I_{ref1} of reference currents I I_{ref0}, I_{ref1}, I_{ref2}, and I_{ref3} according to the size of the selected current signal i₁, and determines the selected reference current as a reference current for the digital signal.

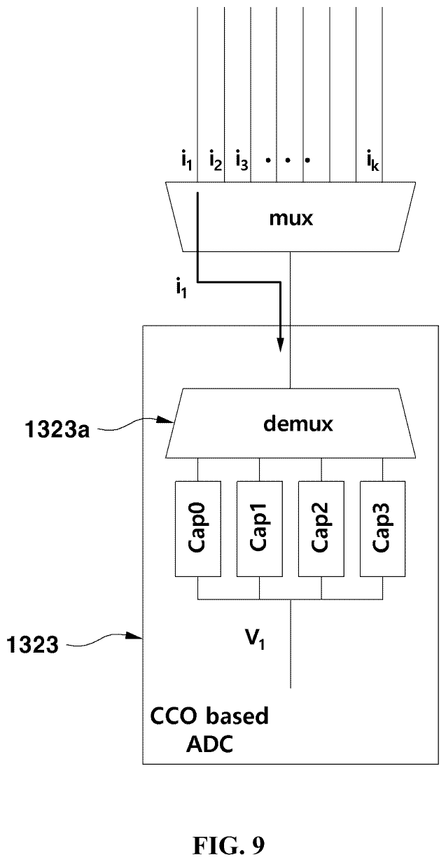

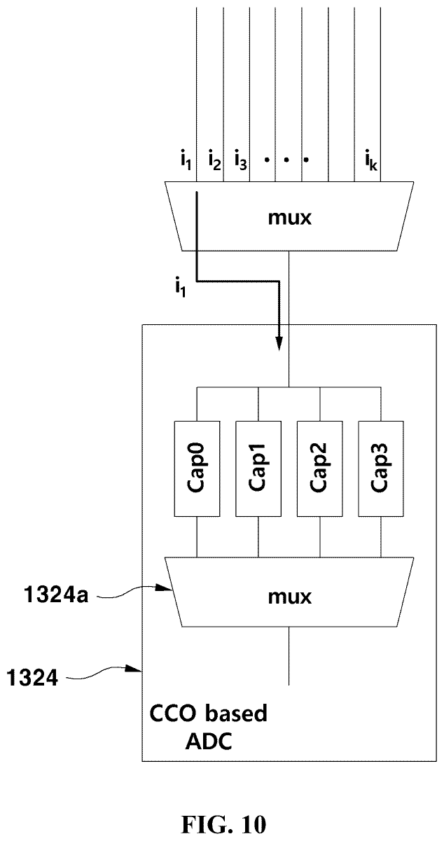

FIGS. 9 and 10 illustrate a process of digitizing a signal through an oscillator-based ADC in an analog computing apparatus according to an embodiment of the invention. In FIG. 9, the oscillator-based ADC includes a plurality of capacitors Cap0, Cap1, Cap2, and Cap3 having different capacitances, and a capacitor is selected through a demultiplexer or multiplexer. The selected capacitor is used to determine an oscillation frequency.

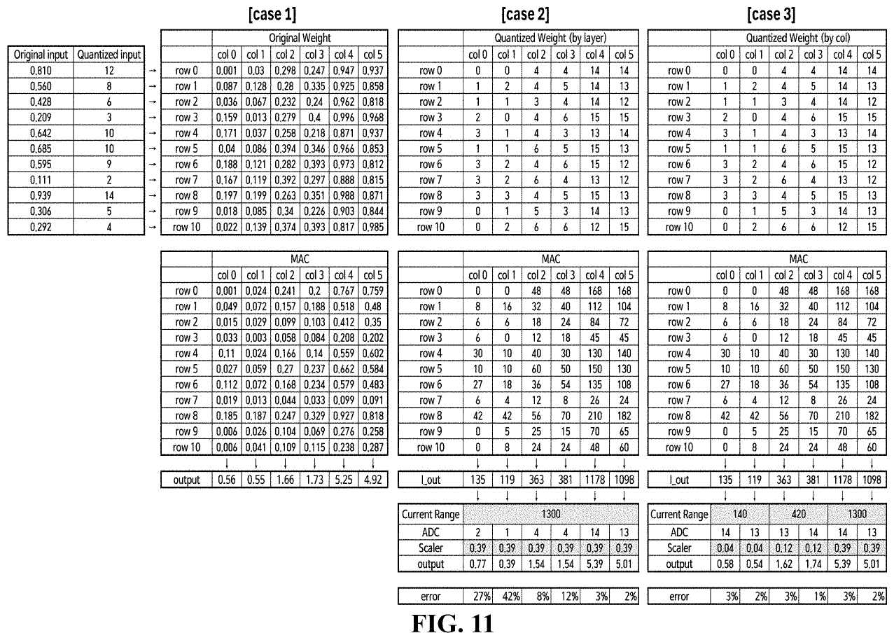

FIG. 11 illustrates a result of digitization of a signal performed through a standard in accordance with the size of a current signal for each output line as described above.

A result of the first calculation (CASE 1) shows a result of a MAC operation in a state in which the digitization is not performed. It shows the result when a weight and an input value are not quantized in the MAC operation. The final result is shown in the bottom line (output). This value may eventually be thought of as an ideal MAC result value.

A result of the second calculation (Case 2) was obtained by digitizing a MAC operation result, which is output after quantizing a weight, through an ADC in one reference current range, and dequantizing the result, thereby outputting a final result. The difference from the first calculation result was up to 42%.

A result of the third calculation (Case 3) was obtained by digitizing a MAC operation result, which is output after quantizing a weight, through an ADC in three reference current ranges, and dequantizing the result, thereby outputting a final result. The difference from the first calculation result was within 3%, which shows an improvement over the second calculation result.

As described above, the analog computing apparatus according to the invention has a flexible standard when performing conversion into a digital signal according to the size of a current signal output for each output line of a memory array in analog computing, and thus, may significantly reduce an error in a result value.

What is claimed is:

1. An analog computing apparatus for performing multiply-accumulate (MAC) operations, the analog computing apparatus comprising:
a memory array including a non-volatile memory cell in which a weight is stored;
an input unit including a digital-analog converter (DAC), thereby inputting an input signal to the memory array;
an output unit including a multiplexer and an analog-to-digital converter (ADC); and
a control unit for controlling the memory array, the input unit, and the output unit, wherein the control unit applies the input signal to the memory array such that the MAC operation is performed through the weight, selects a current signal output from each of a plurality of output lines of the memory array, which are the results of the MAC operation, one by one through the multiplexer, classifies the grade of the selected current signal according to a current size, controls the current signal according to the classified grade, and converts the current signal into a digital signal through the analog-digital converters.

2. The analog computing apparatus of claim 1,
wherein the output unit comprises a plurality of I-V converters, wherein the multiplexer is disposed between the output line of the memory array and the plurality of I-V converters, and the plurality of I-V converters are connected in parallel to each other and have different resistances or different capacitances, and the control performed by the control unit according to the classified grade is to convert the selected current signal into a voltage signal through any one of the plurality of I-V converters according to the classified grade and transmit the voltage signal to the analog-digital converter.

3. The analog computing apparatus of claim 2, further comprising a demultiplexer disposed between the multiplexer and the plurality of I-V converters,
wherein the control performed by the control unit according to the classified grade is to send the selected current signal to any one of the plurality of I-V converters through the demultiplexer according to the classified grade, thereby converting the selected current signal into a voltage signal, and transmit the voltage signal to the analog-digital converter.

4. The analog computing apparatus of claim 2, further comprising an additional multiplexer disposed between the plurality of I-V converters and the analog-digital converter,
wherein the control performed by the control unit according to the classified grade is to transmit the selected current signal to all of the plurality of I-V converters, select one of the plurality of voltage signals converted from the plurality of I-V converters through the additional multiplexer according to the classified grade, and transmit the selected voltage signal to the analog-digital converter.

5. The analog computing apparatus of claim 1,
wherein the output unit comprises an I-V converter disposed between the multiplexer and the analog-digital converter, wherein the analog-digital converter is a voltage-mode ADC, and the control performed by the control unit according to the classified grade is to change a reference voltage of the voltage-mode ADC according to the classified grade of the selected current signal.

6. The analog computing apparatus of claim 1,
wherein in the output unit, the analog-digital converter is a current-mode ADC, and the control performed by the control unit according to the classified grade is to change a reference current of the current-mode ADC according to the classified grade of the selected current signal.

7. The analog computing apparatus of claim 1,
wherein in the output unit, the analog-digital converter is an oscillator-based ADC and has a plurality of capacitors having different capacitances thereinside, and the control performed by the control unit according to the classified grade is to allow the selected current signal to use any one of the plurality of different capacitors in the oscillator-based ADC according to the classified grade.

8. An analog computing method for storing a weight in a non-volatile memory device disposed in a memory array and performing a multiply-accumulate (MAC) operation by using the weight, the method comprising:
(a) a weight storage step of storing the weight, which is included in each layer in a model of a neural network including a plurality of layers, in the non-volatile memory device disposed in the memory array;
(b) a MAC operation step of applying an input signal to the memory array, thereby performing the MAC operation, and outputs the M A C operation result as a current signal;
(c) a step of determining a grade of the current signal output for each output line of the memory array according to a current size; and
(d) a step of controlling the current signal according to the determined grade, thereby converting the current signal into a digital signal.

9. The method of claim 8,
wherein the determination of the grade in the step (c) is a result predicted according to the neural network model.

10. The method of claim 8,
wherein the determination of the grade in the step (c) is a result obtained through sensing the current signal for each output line.
